(19) United States
(12) Patent Application Publication
(10) Pub. No.: US 2023/0422420 A1
(43) Pub. Date: Dec. 28, 2023

(54) SCALABLE MODULAR INTERNET-OF-THINGS DEVICE

(71) Applicant: C&TECH, Daejeon (KR)

(72) Inventors: Ki Duk KIM, Daejeon (KR); Seung Hyun PARK, Sejong-si (KR)

(73) Assignee: C&TECH, Daejeon (KR)

(21) Appl. No.: 17/909,754

(22) PCT Filed: Nov. 5, 2021
(86) PCT No.: PCT/KR2021/015990

§ 371 Date: Sep. 6, 2022

(30) Foreign Application Priority Data
Feb. 26, 2021 (KR) 10-2021-0026882
Oct. 26, 2021 (KR) 10-2021-0143267

(51) Int. Cl. H05K 5/02; H05K 5/00

(52) U.S. Cl. CPC H05K 5/0247; H05K 5/0086

(57) ABSTRACT

One aspect of the present disclosure discloses an expandable modular IoT device. The device comprises a first substrate, a first processor on the first substrate, a first IoT sensor on the first substrate, and a connector configured to connect an additional electronic component.

### BACKGROUND

### Technical Field

The present disclosure relates to an IoT terminal and more particularly, to a method for expanding an IoT device.

### Background Art

The Internet of things (IoT) is defined as the Internet of physical things or Internet of objects and refers to an environment in which information generated by uniquely identifiable objects is shared over the Internet. The IoT is a concept originating from the existing Ubiquitous Sensor Network (USN) and Machine to Machine (M2M) and has evolved to be regarded as the Internet of Everything (IoE).

The Internet of Things may share information by connecting objects through a network, not only in home appliances and electronic devices but also in various fields such as healthcare, remote meter reading, smart home, and smart car.

As IoT technology advances, attempts to expand and utilize multiple IoT sensors are being made in response to various user requests. To this end, individual IoT-related components should be easily expanded in conjunction with each other, however, the following problems occur when the existing IoT terminals are to be expanded.

FIG. 1 illustrates a process of expanding the battery of an existing IoT terminal.

Referring to FIG. 1, when a request to add battery 2 is raised to extend and apply power supply to an IoT device 100 including a processor 120, IoT sensor 1 130, and battery 1 140, a conventional technique deals with the request by adding battery 2 150 together with battery 1 140 inside the IoT device 105. As described above, since the IoT device 105 with newly added battery 2 150 may not be obtained by simply attaching related components to the IoT device 100, a structural change of the entire device is inevitable, which causes inconvenience. In addition, in the case the existing IoT device 100 has already passed various certification tests, the new IoT device 105 obtained from the existing IoT device after an excessive design change needs to undergo the certification tests again, which causes another inconvenience.

FIG. 2 illustrates a process of adding an IoT sensor to an existing IoT terminal. Also, the case of FIG. 2 is similar to that of FIG. 1.

Referring to FIG. 2, when a request to add a sensor is raised for an IoT device 100 in the same form of the IoT device 100 in the left area of FIG. 1 to expand the device functionality, a conventional technique deals with the request by adding IoT sensor 2 160 on a first substrate 110 of the IoT device 105. At this time, since the IoT device 100 is not structured in the form of a simple combination, the entire first substrate 110 needs to be newly developed, which accordingly involves newly developing the entire IoT device 105. Therefore, a burden of changing the overall structure exists, and as illustrated in the example of FIG. 1, when the existing IoT device 100 has passed various certification tests, the new IoT device 105 obtained from the existing IoT device after an excessive design change needs to undergo the certification tests again, which causes inconvenience.

### SUMMARY

An object according to one aspect of the present disclosure to solve the problem above is to modularize an IoT device and provide an expandable modular IoT device capable of creating a new product by assembling necessary function modules according to business directions.

To achieve the object above, an expandable modular IoT device according to one aspect of the present disclosure may comprise a first substrate, a first processor on the first substrate, a first IoT sensor on the first substrate, and a connector configured to connect an additional electronic component.

The device may further include a first battery arranged within the IoT device.

The additional electronic component may further include a second battery and a power management circuit controlling the power from the second battery, wherein the power management circuit (i) may supply the power from the first battery to the processor when only the first battery is connected and (ii) may supply the power from the second battery to the processor when the second battery arranged independently of the IoT device is connected to the connector.

When the connector is connected to a charging Universal Serial Bus (USB), the power management circuit may supply power to the processor at a second voltage through the charging USB, wherein the second voltage may be higher than a first voltage of the first battery or the second battery.

In response to the existence of the first battery with the connector connected to the charging USB, the power management circuit may activate a mode for charging the first battery while supplying power to the processor at the second voltage.

The additional electronic component includes a second substrate and a second IoT sensor on the second substrate, and when the second substrate and the second IoT sensor are arranged inside the IoT device, the connector is a first internal connector arranged on the first substrate, wherein a second internal connector is also arranged on the second substrate, and wherein the first substrate and the second substrate may be modularized and communicate within the IoT device due to a connection between the first internal connector and the second internal connector.

The connector may be a first external connector for connection with a second IoT device arranged independently of the IoT device, wherein the second IoT device may also include a second processor, a second IoT sensor, and a second external connector, and wherein the first external connector may be connected to the second external connector to enable the first processor to communicate with the second processor.

Communication manners through the connector may include at least one of the Universal Asynchronous Receive/Transmit (UART), Inter-Integrated Circuit (I2C), and Serial Peripheral Interface (SPI) communication.

The communication manner between the first processor and the first IoT sensor may use a first communication manner, wherein the communication manner between the first substrate and the second substrate within the IoT device through an internal connector may use a second communication manner, and wherein a communication manner for a second IoT device through an external connector may use a third communication manner for transmission and reception of data.

To achieve the object above, an expandable modular IoT device according to another aspect of the present disclosure may comprise a first substrate, a processor on the first substrate, a first IoT sensor on the first substrate, and an antenna operating in conjunction with the processor, wherein other derived electronic components than the first substrate, the processor, and the first IoT sensor may be configured to be mounted inside the IoT device.

A component arrangement prohibition area having a size greater than or equal to a reference value may be set in a predetermined area of a side of the antenna in the horizontal direction from the bottom surface of the IoT device, and when the derived electronic component is expanded and made to operate in conjunction with other components, no component is configured to be arranged in the component arrangement prohibition area to prevent the Radio Frequency (RF) performance of the processor and the antenna from being affected.

The antenna is arranged on top of the processor in the vertical direction from the bottom surface, wherein the antenna is arranged around the first substrate in the horizontal direction, and wherein the length of the antenna is shorter than the length of the first substrate by more than a reference length such that the component arrangement prohibition region may be formed to secure the predetermined area in a marginal portion between the length of the first substrate and the length of the antenna.

A fixed area is formed, which includes the antenna, the processor, the first IoT sensor, and the first substrate, wherein the derived component is formed in an expansion area and operates in conjunction with a single IoT device, wherein the expansion area may be formed on a side surface of the fixed area in the horizontal direction.

The expansion area may have a limited space so that the expansion area's height does not exceed a reference value.

The derived component may include at least one of a second substrate, a second IoT sensor, and a battery.

An expandable modular IoT device of the present disclosure minimizes the need to develop a new product and a certification procedure.

Also, the expandable modular IoT device may quickly respond to the needs of various IoT markets.

In addition, the present disclosure has an effect of providing efficient product scalability since the expandable modular IoT device may be used in connection with a third-party sensor terminal or board already developed. In other words, by connecting a communication module to a third-party sensor terminal, an IoT integrated solution may be easily built without newly developing a communication module/antenna/server/web/app.

### BRIEF DESCRIPTION OF THE DRAWINGS

FIG. 1 illustrates a process of expanding the battery of an existing IoT terminal.

FIG. 2 illustrates a process of expanding an IoT sensor of an existing IoT terminal.

FIG. 3 is a block diagram illustrating an expandable modular IoT device according to one embodiment of the present disclosure.

FIG. 4 is a block diagram illustrating a structure of expanding the battery of the expandable modular IoT device of FIG. 3.

FIG. 5 illustrates a method for controlling a power path depending on a power source for the battery expansion structure of FIG. 4.

FIG. 6 is a block diagram illustrating a structure of expanding an IoT sensor of the expandable modular IoT device of FIG. 3.

FIG. 7 is a block diagram illustrating a structure in which the IoT sensor of FIG. 6 is expanded inside the IoT device.

FIG. 8 is a block diagram illustrating a structure in which an external IoT device is combined with the IoT device of FIG. 7.

FIG. 9 is a block diagram illustrating the need for additionally developing an external connector structure based modular IoT device.

FIGS. 10 and 11 are a cross-sectional view and a top view of an expandable modular IoT device according to another embodiment of the present disclosure.

FIGS. 12 to 14 illustrate an expansion structure in which additional IoT-related components are connected to the IoT devices of FIGS. 10 and 11.

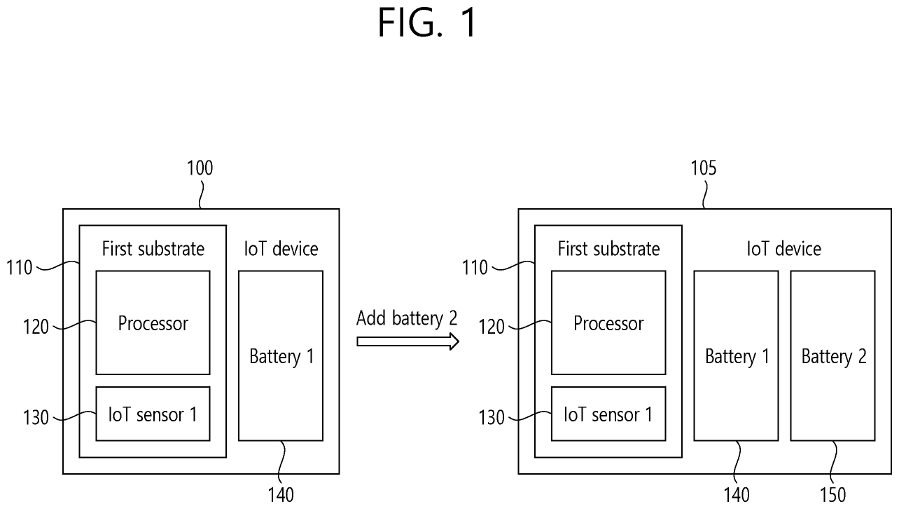

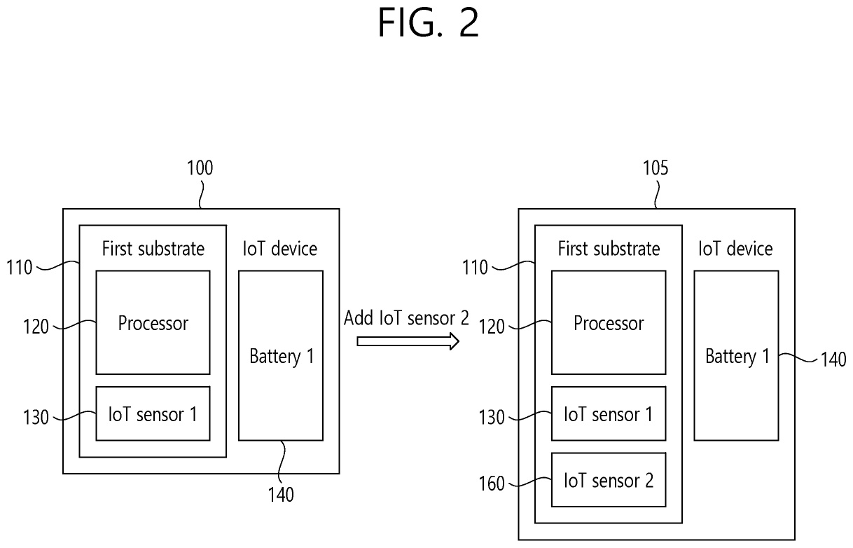

### DETAILED DESCRIPTION OF THE DISCLOSURE

Since the present disclosure may be modified in various ways and may provide various embodiments, specific embodiments will be depicted in the appended drawings and described in detail with reference to the drawings.

However, it should be understood that the specific embodiments are not intended to limit the gist of the present disclosure to the specific embodiments, rather, it should be understood that the specific embodiments include all of the modifications, equivalents or substitutes belonging to the technical principles and scope of the present disclosure.

Terms such as first and second may be used to describe various constituting elements, but the constituting elements should not be limited by the terms. The terms are introduced to distinguish one element from the others. For example, without departing from the technical scope of the present disclosure, a first element may be referred to as a second element, and similarly, the second element may be referred to as the first element. The term and/or includes a combination of a plurality of related, disclosed items or any one of a plurality of related, disclosed items.

When a constituting element is said to be “connected” or “attached” to another constituting element, the former may be connected or attached to the latter element directly, but it should be understood that a third constituting element may be present between the two elements. On the other hand, when a constituting element is said to be “directly connected” or “directly attached” to another constituting element, it should be understood that there is no other constituting element present between the two elements.

Terms used in the present disclosure are intended only for describing a specific embodiment and are not intended to limit the technical scope of the present disclosure. A singular expression should be understood to indicate a plural expression unless otherwise explicitly stated. The term “include” or “have” is used to indicate existence of an embodied feature, number, step, operation, element, component, or a combination thereof, and should not be understood to preclude the existence or possibility of adding one or more other features, numbers, steps, operations, elements, components, or a combination thereof.

Unless defined otherwise, all the terms used in the present disclosure, including technical or scientific terms, provide the same meaning as understood generally by those skilled in the art to which the present disclosure belongs. Those terms defined in ordinary dictionaries should be interpreted to have the same meaning as conveyed in the context of related technology. Unless otherwise defined explicitly in the present disclosure, those terms should not be interpreted to have ideal or excessively formal meaning.

In what follows, with reference to appended drawings, preferred embodiments of the present disclosure will be described in more detail. In describing the present disclosure, to help overall understanding, the same reference symbols are used for the same elements in the drawings, and repeated descriptions of the same elements will be omitted.

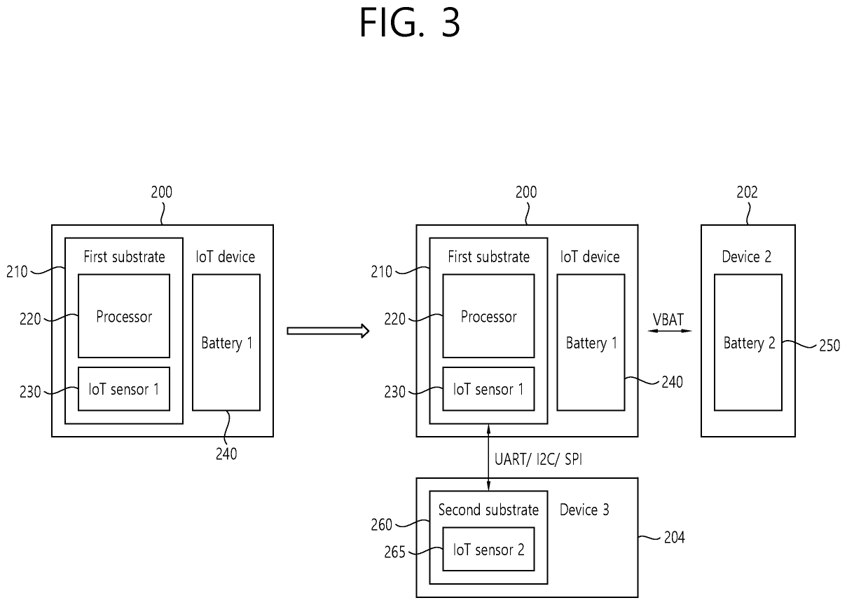

FIG. 3 is a block diagram illustrating an expandable modular IoT device according to one embodiment of the present disclosure. As shown in FIG. 3, an expandable modular IoT device 200 according to one embodiment of the present disclosure may comprise a substrate 210, a processor 220, an IoT sensor 230, and a battery 240.

Referring to the left drawing of FIG. 3, the IoT device 200 has a structure in which the processor 220 and the IoT sensor 230 are electrically connected and arranged on the substrate 210, and the battery 240 is electrically connected to the substrate 210 to supply power.

Here, the substrate 210 may be implemented using a breadboard, an Arduino board, or a PCB board.

The processor 220 may be implemented using a microprocessor and/or a microcontroller unit (MCU). The processor 220 may include a communication module. The MCU and the communication module may be implemented within one processor or using independent processors. At this time, the communication module supports various radio frequency (RF) techniques. For example, the communication module may support short-distance communication such as Bluetooth, Zigbee, and Wi-Fi and broadband communication such as LTE and 5G. More preferably, the communication module may support communication manners such as LoRa and NB-IoT, which are communication manners for IoT devices. The processor 220 may operate based on the source code describing IoT operation information. Being connected to a different computing device, the processor 220 may perform various control functions as a user inputs a source code related to IoT operation information through an input device such as a keyboard and a mouse.

The IoT sensor 230 represents a sensing device that detects or measures a physical quantity or a change of the physical quantity such as temperature, pressure, light, or sound and converts the detected or measured physical quantity into an electrical signal. The IoT sensor may include a light sensor, a proximity sensor, a moisture sensor, an ultrasonic sensor, a water quality sensor, a water level sensor, a motion sensor, a gyroscope sensor, an image sensor, a heat/smoke sensor, an infrared sensor, a chemical sensor, a vibration sensor, a temperature sensor, a pressure sensor, a gas sensor, an acoustic sensor, a quartz crystal microbalance (QCM), an electrostatic probe (Langmuir probe), a magnetic probe, a spectroscope or an ionic mass spectrometer, however, the IoT sensor is not necessarily limited to the specific examples above. In some cases, the IoT device may include a digital input/output peripheral device such as an LED and a switch and/or a Pulse Width Modulation (PWM) input/output peripheral device such as a DC motor and a servomotor.

Referring to the right drawing of FIG. 3, a component such as a battery and/or an IoT sensor may be added to the IoT device 200 to change the hardware specification. At this time, added electronic components may include various electronic parts (such as a memory) as well as a battery or an IoT sensor.

First, to expand a power function, device 2 202 including the battery 250 may be connected. In this case, power may be supplied at a VBAT voltage to the IoT device 200 without an excessive design change using a connector. To this end, the IoT device 200 (device 1) is also built in a modular form including a connector (not shown) to receive or output power. Also, it is preferred that device 2 202 includes a connector to be modularized. Accordingly, the connector of the IoT device 200 and the connector of device 2 202 may be coupled to transmit/receive power at the VBAT voltage.

In another example, the IoT device 200 may be connected to device 3 204 including IoT sensor 2 265 to expand a sensing function. To this end, a separate connector in a form different from a power connector or based on a different communication manner may be arranged. Device 3 204 may be built in a form in which IoT sensor 2 265 is electrically connected to the second substrate 260 and may have a modular structure including an external connector. Through the structure above, the IoT sensor 265 may be coupled through the separate connector of device 1 200 and the connector of device 3 204. The connection between the connectors may be established using at least one of the Universal Asynchronous Receive/Transmit (UART), Inter-Integrated Circuit (I2C), and Serial Peripheral Interface (SPI) communication. UART is asynchronous communication, which uses a manner for replacing a synchronization signal (Clock) to transmit and receive data smoothly. Since UART communication does not define a shared clock, it is desirable to configure and match the same timing (baud rate) to decode data correctly. I2C communication is a manner for transmitting and receiving data through one line (SDA) for sending and receiving data and one clock line (SCL) for synchronizing transmission/reception timing. I2C communication consists of one master and one or more slaves and may connect up to 127 slaves. The SPI manner is a synchronous communication manner supporting 1:N communication. For SPI communication, there has to be one master and one or more slave devices. Since SPI communication uses a separate line for data transmission and reception, transmission and reception may be performed simultaneously, which is faster than I2C communication consisting of one line for transmitting and receiving data. Therefore, it is preferable to use SPI communication for applications where communication speed is important, such as Ethernet communication.

According to another embodiment of the present disclosure, other IoT-related components may be modularized and coupled through a connector in addition to the battery and the IoT sensor. For example, electronic components such as a memory, another processor, an encoder/decoder, and a converter/inverter may also be modularized and coupled through a connector. At this time, if device 1 has a female connector, device 2 should have a corresponding male connector. For example, if one device has a protruding pin, the other device preferably has a connector shaped to receive the protruding pin. Modularization means configuring not only one component but also a plurality of components in a form that may be combined with other devices or components without special processing including internal or external connectors.

According to an additional embodiment of the present disclosure, when the IoT device 200 is viewed from the ground in the vertical direction, modularized electronic components may be configured to be connectable by arranging power-related connectors in both side directions, namely, left and right directions to connect a power-related modularized device such as a battery and by arranging data transmission/reception function connectors (UART, I2C, or SPI-based connectors) including sensors in two directions, namely, upward and downward directions. The arrangement may also be made the other way round. In this case, a plurality of connectors may be arranged on one surface. In addition to the battery-related devices 202 coupled to the IoT device 200, electronic component-related devices 204 may be configured to be coupled to the IoT device 200 and, at the same time, connected to other devices by arranging one or more connectors on their left and right sides and/or top and bottom sides. Various IoT devices may be linked and implemented in an indefinitely expandable, modular form through the configuration above. Accordingly, a plurality of battery modules and/or a plurality of IoT sensor modules may be combined on one surface.

Additionally, a connector may be arranged not only on the upper side but also on the lower side in a direction perpendicular to the ground. Accordingly, connectors may be arranged on both sides, thereby allowing a more flexible connection to be made.

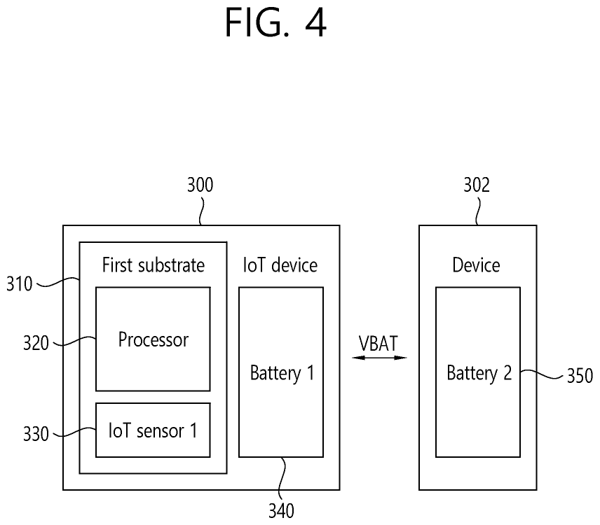

FIG. 4 is a block diagram illustrating a structure of expanding the battery of the expandable modular IoT device of FIG. 3.

Referring to FIG. 4, when an IoT device 300, which comprises a processor 320 (including an MCU and a communication module) and an IoT sensor 330 arranged on a first substrate 310 along with battery 1 340, needs to be newly developed due to expansion of a battery function, modularized device 2 302 including a battery 350 may be simply connected without changing the overall device structure. At this time, without an excessive design change of the IoT device 300, power may be supplied at VBAT voltage using a power connector. In this case, one of the power connectors of the two devices 300, 302 may be formed to have a plurality of protruding pins, and the other may be formed to accommodate the protruding pins. Moreover, connectors may be provided on different surfaces to improve the degree of freedom of hardware assembly and connection. For example, suppose a connector is provided on the upper surface of device 1 300, then, another connector is provided on the lower surface of device 2 302 so that the two devices may be easily attached to and detached from each other. As described above, configuring both devices 300, 302 to be easily expandable in a modular form avoids the need to develop an additional communication module and perform various certification tests despite the hardware specification change due to battery expansion. In other words, it is sufficient to additionally develop, modularize, and install only the part changed due to the connection to device 2 302.

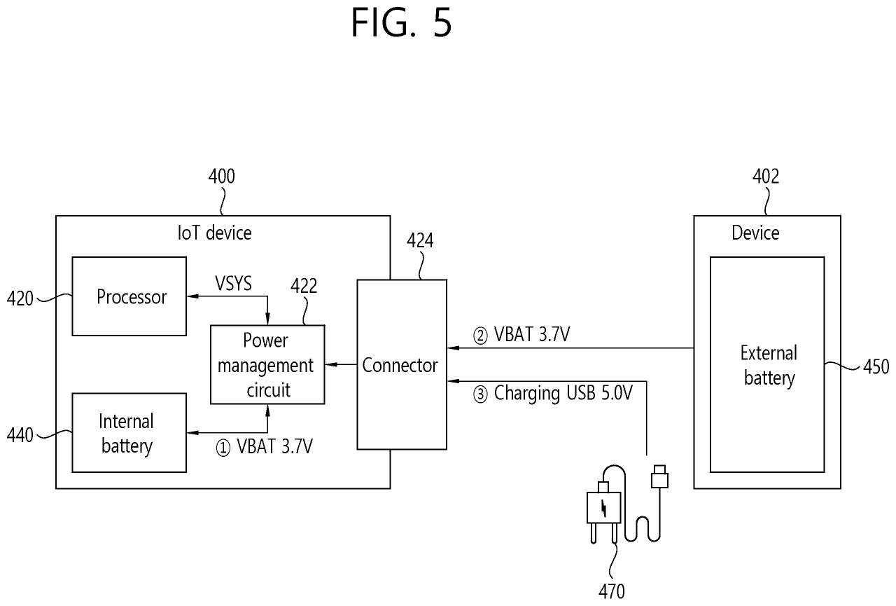

FIG. 5 illustrates a method for controlling a power path depending on a power source for the battery expansion structure of FIG. 4.

Referring to FIG. 5, appropriate power control may be required when the IoT device 400 is expanded to connect to various power sources. First, as described above, the IoT device 400 is provided with a processor 420 on a substrate, where a power management circuit 422 controls a power path so that VSYS voltage flows into the processor 420. The power management circuit 422 is connected to an internal battery 440 and/or a connector 424 to receive power from the outside and, depending on a connection relationship, performs a function of supplying power VSYS to the processor 420 based on an appropriate scenario.

According to an embodiment of the present disclosure, the power management circuit 422 controls the power path according to a connected power source and forms a structure that enables not only charging of the internal battery 440 but also battery expansion with one connector 424.

First, when only the internal battery 440 is connected, the power VSYS supplied to the processor 420 comes from the internal battery 440. In this case, the voltage VSYS may be 3.7V, which is the voltage VBAT of a built-in small battery.

Next, when only the external battery 450 is connected through the connector 424, the power VSYS supplied to the processor 420 comes from the external battery 450. In this case, the voltage VSYS may be 3.7V, which is the voltage VBAT of an external auxiliary battery.

Similarly, when only the charging USB 470 is connected to the connector 424 to draw power through the charging USB 470, the power VSYS supplied to the processor 420 comes through the charging USB. In this case, although the voltage of the charging USB is 5.0V, the power management circuit 422 sets the voltage VSYS to 4.2V and supplies the set voltage to the processor 420 for stable power supply.

Additionally, when the internal battery 440 is connected to the external battery 450 through the connector 424, the power VSYS supplied to the processor 420 is made to come from the external battery 450. If the external auxiliary battery is also made to charge the internal battery 440, an excessive load is applied to the external auxiliary battery 450, thus, a charging mode is controlled to maintain an inactive state.

In another example, when the internal battery 440 is connected to the charging USB 470 through the connector 424, the power VSYS supplied to the processor 420 is made to come through the charging USB 470. Accordingly, the voltage VSYS may be set to 4.2V and provided to the processor 420. At this time, since the charging USB 470 may receive power stably, it is preferable to charge the internal battery 440 as well. Therefore, while the voltage VSYS is supplied stably at 4.2V, the charging mode of the internal battery 440 is activated so that charging of the internal battery 440 may also be performed.

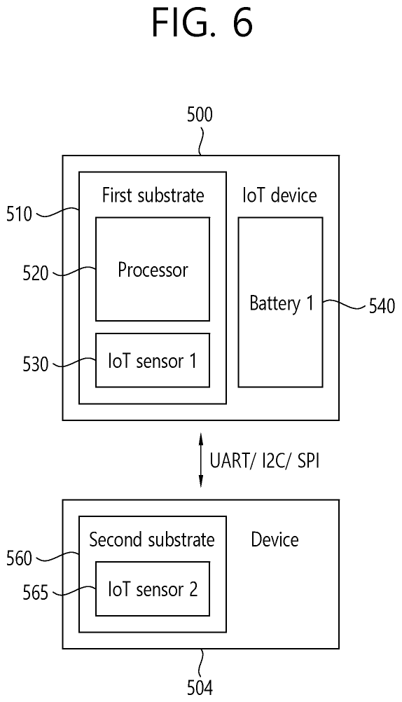

FIG. 6 is a block diagram illustrating a structure of expanding an IoT sensor of the expandable modular IoT device of FIG. 3.

Referring to FIG. 6, a modular IoT device 500 having the same structure as the IoT device of FIG. 3 may be coupled with a device 504 to expand its functionality. At this time, the IoT device 500 may be connected through a connector (not shown). The device 504 is connected to the IoT device 500 by being modularized based on a connector (not shown) in a shape corresponding to the connector of the IoT device 500. The device 504 includes IoT sensor 2 565 on a second substrate 560. The connection between the two connectors may be established using at least one of the UART, I2C, and SPI communication.

According to the use case of the two modular devices 500, 504 as described above, even when product development is required for a new function, it suffices to develop and connect only the part that is changed as a module without involving an excessive design change, thus, the efficiency of product development may be increased, and benefits may be obtained in terms of development cost.

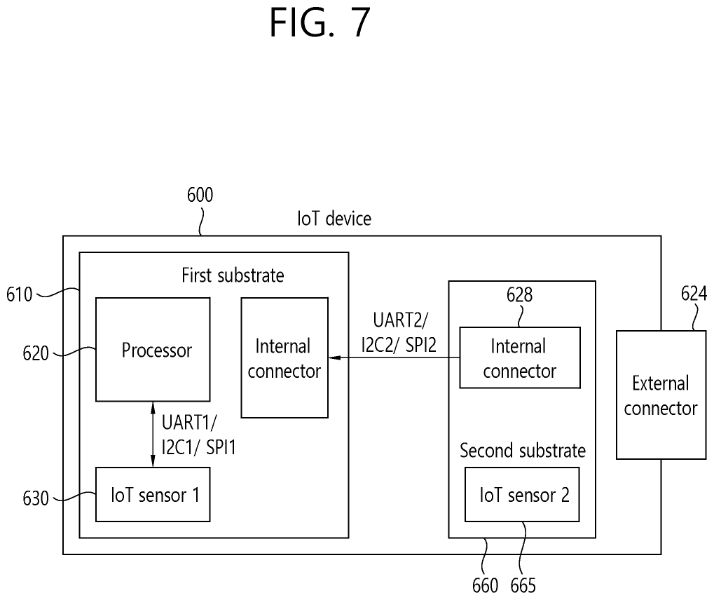

FIG. 7 is a block diagram illustrating a structure in which the IoT sensor of FIG. 6 is expanded inside the IoT device.

Referring to FIG. 7, expansion of a device does not necessarily indicate connecting only to an electronic component outside the device. It is also possible to expand a device to an internal electronic component. In other words, a modular IoT device 600 may be designed as an embedded sensor type.

More specifically, the IoT device 600 arranges a processor 620 (which may include an MCU and a communication module) and an IoT sensor 630 on a first substrate 610, and the first substrate 610 includes an internal connector 626. At this time, the processor 620 and the IoT sensor 630 within the IoT device 600 may be connected through at least one of the UART, I2C, and SPI communication manners to exchange data.

Also, the IoT device 600 includes an IoT sensor 665 and an internal connector 628 on a second substrate 660. The two substrates 610, 660 may be connected through at least one of the UART, I2C, and SPI communication manners to exchange data. The processor 620 may select a communication manner based on the communication manner supported by the IoT sensor 665. The internal connectors 626, 628 are intended to transmit and receive data and may have shapes corresponding to each other.

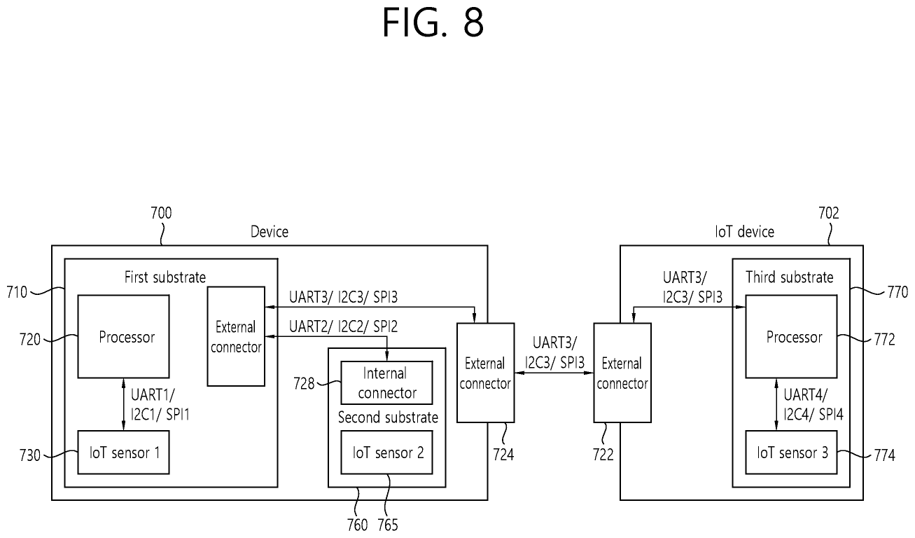

FIG. 8 is a block diagram illustrating a structure in which an external IoT device is combined with the IoT device of FIG. 7.

Referring to FIG. 8, the IoT device 700 on the left side of FIG. 8 has the same configuration as the IoT internal expansion type IoT device 600 of FIG. 7. A pre-developed third-party IoT sensor device 702 may be connected to the IoT device 700. The IoT sensor device 702 includes a processor 772 and IoT sensor 3 774 on a third substrate 770. The processor 772 and IoT sensor 3 774 within the IoT sensor device 702 may also be connected to each other through at least one of the UART, I2C, and SPI communication manners to transmit and receive data.

Meanwhile, the connection between the two devices 700, 702 may be made through external connectors 724, 722. By connecting to the IoT device 700 through the external connector 724, the IoT device 702 may build an IoT integrated solution without developing a separate communication module, antenna, server, web, and application. In this case, the internal connectors 726, 728 and the external connectors 724, 722 may have different shapes or use different communication manners. The IoT device 700 may select at least one of the UART, I2C, and SPI communication manners according to whether the MCU of the processor 772 of the IoT device 702 supports the selected communication manner.

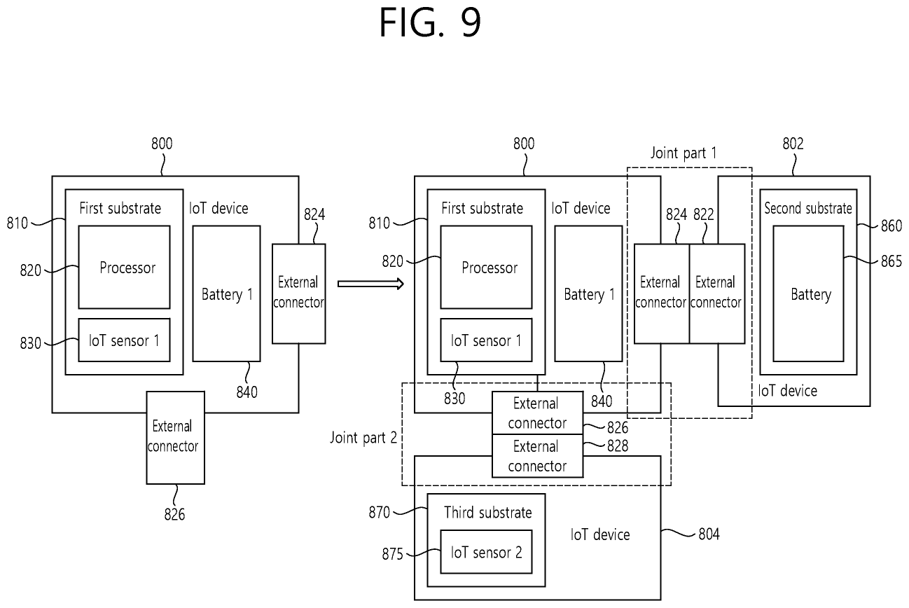

FIG. 9 is a block diagram illustrating the need for additionally developing an external connector structure based modular IoT device.

Referring to FIG. 9, according to one embodiment of the present disclosure, an IoT device 800 having a plurality of external connectors 824, 826 may be connected to an IoT device 802 and another IoT device 804 using an external connector 822 and another external connector 828 due to the need for developing a new product according to the change of hardware specifications.

In particular, referring to the drawing on the right side of FIG. 9, modular IoT devices based on an external connector connection structure are fabricated so that the devices 802, 804 match the IoT device 800. At this time, there is a burden of developing all of a case for the IoT device 802, a second substrate 860, a battery 865, a case for the IoT device 804, a third substrate 870, and IoT sensor 2 875.

In particular, a reliability issue related to waterproofing, dust proofing, or durability may occur at joint part 1 of the IoT device 800 and the IoT device 802 and joint part 2 of the IoT device 800 and the IoT device 804. Also, it is inevitable to increase the product size due to reinforcing the joint parts. In addition, the antenna performance may vary due to a radiation pattern depending on internal components and mechanism type, a problem exists that the antenna performance of the IoT device 800 is affected by adding a new mechanism to the IoT device 802.

As a result, the external connector mounting type is not effective in terms of product miniaturization and antenna radiation efficiency. More specifically, essential factors to consider when designing IoT devices are miniaturization, water and dust resistance, and RF performance. Therefore, it is desirable to minimize the development cost and time by keeping the development and review of the considerations above to a minimum when a product line is increased. An integrated mechanism may be appropriate when an external connector is applied since a space of 20 to 30% or more of the size is wasted for small-sized products. In other words, performing modularization within the mechanism may be desirable.

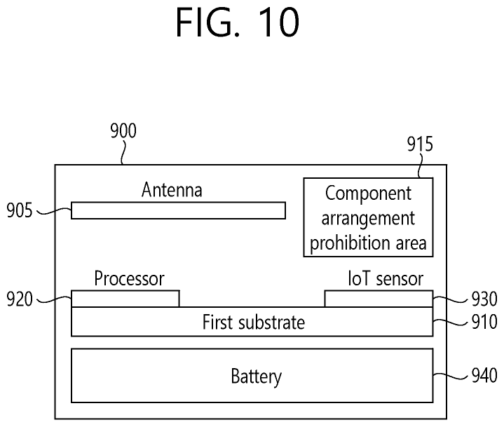

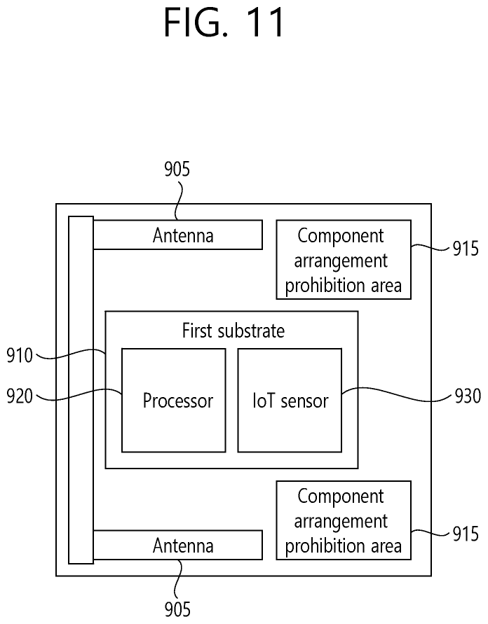

FIGS. 10 and 11 are a cross-sectional view and a top view of an expandable modular IoT device according to another embodiment of the present disclosure.

Referring to FIG. 10, when viewed in a cross-sectional view, the IoT device 900 comprises a battery 940, a first substrate 910, a processor 920, an IoT sensor 930, and an antenna 905. At this time, the battery 940 may be arranged at the bottom, the first substrate 910 may be arranged on top of the battery 940, the processor 920 may be arranged on one side surface of the first substrate 910, and the IoT sensor 915 may be electrically connected to the other side. The processor 920 and the IoT sensor 915 may be arranged side by side on the first substrate 910. The antennas 905 may be spaced apart above the processor 920. Here, the processor 920 may be a communication module and may transmit and receive a wireless signal in conjunction with the antenna 905. In this arrangement, it is preferable to set a component arrangement prohibition area 915 in a side surface area of the antenna 905 in the IoT device 900 so that electronic components are prohibited from being arranged. In other words, it is preferable to configure electronic components to be not arranged arbitrarily so that the RF performance of the processor 920 and the antenna 905 is not affected.

Referring to FIG. 11, when viewed in a top view, a processor 920 may be arranged on the left side of the first substrate 910, and an IoT sensor 930 may be arranged on the right side of the first substrate 910. The antenna 905 may be arranged around the first substrate 910, surrounding the first substrate 910. The antenna 905 may be arranged on the upper and lower part of the first substrate 910 and may also be arranged on one side of the left or right side. Since the antenna 905 operates in conjunction with the processor 920, it is arranged on a side surface corresponding to the processor 920. Accordingly, when the antenna 905 is arranged to be placed on the left side of the first substrate 910, the component arrangement prohibition area 915 may be set on the right side of the antenna 905. In particular, when the length of the first substrate 910 is compared with the length of the antenna 905, the component arrangement prohibition area 915 may be arranged in a marginal portion between the lengths. In this case, it is preferable for the component arrangement prohibition area 915 to have a predetermined area greater than or equal to a reference value. To secure the reference area, the length of the antenna 905 should be shorter than the length of the first substrate 910 by more than a reference length. It is preferable that the component arrangement prohibition area 915 should be configured to have a size greater than or equal to at least 4 cm².

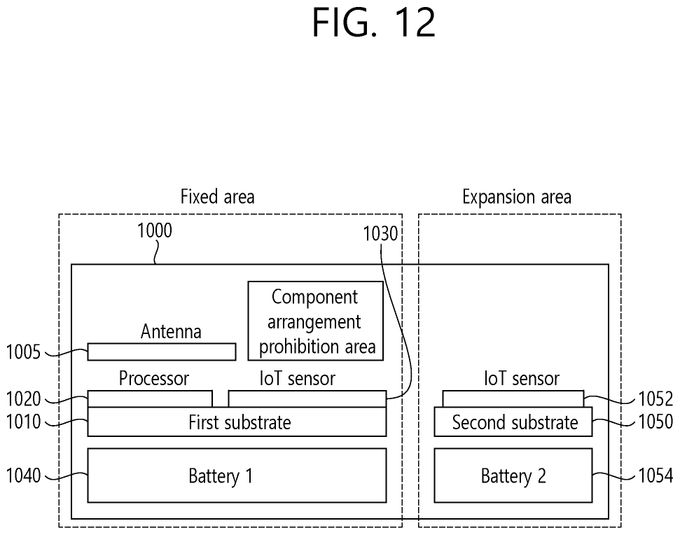

FIGS. 12 to 14 illustrate an expansion structure in which additional IoT-related components are connected to the IoT devices of FIGS. 10 and 11.

Referring to FIG. 12, a fixed area of an IoT device (the IoT device having basic components of FIGS. 10 and 11 in a modular form) comprises an antenna 1005, a first substrate 1010, a processor 1020, an IoT sensor 1030, and battery 1 1040. Also, by adding a component arrangement prohibition area, no components are configured to be arranged in the corresponding area. Also, an expansion area is designated in the horizontal direction of the fixed area so that derived electronic components may be arranged only in the expansion area according to a new hardware specification. In other words, devices may be derived without a limit in a free form within the expansion area. In the embodiment of FIG. 12, an IoT device including IoT sensor 2 1052 and battery 2 1054 on a second substrate 1050 is internally modularized and expanded into one device without employing an external connector.

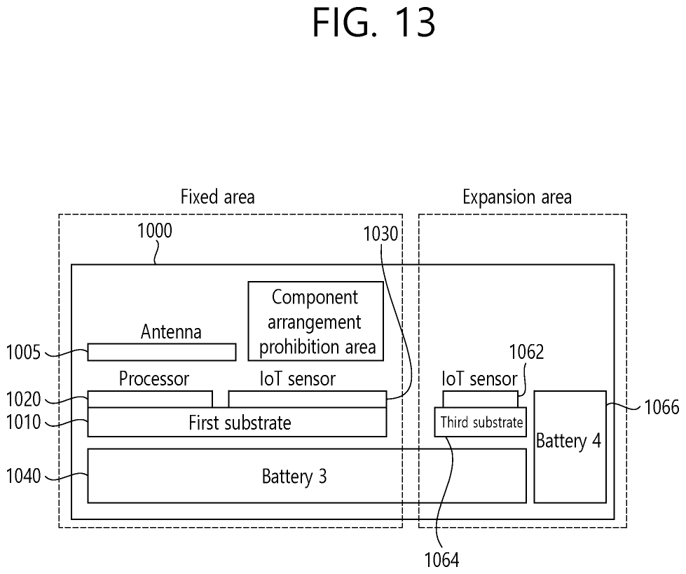

Referring to FIG. 13, battery 3 1040 in a fixed area is stretched to an expansion area, making the width of the battery longer, in addition to the battery, an IoT device including IoT sensor 3 1062 and battery 4 1066 are internally modularized and configured in an expanded form on a third substrate 1060.

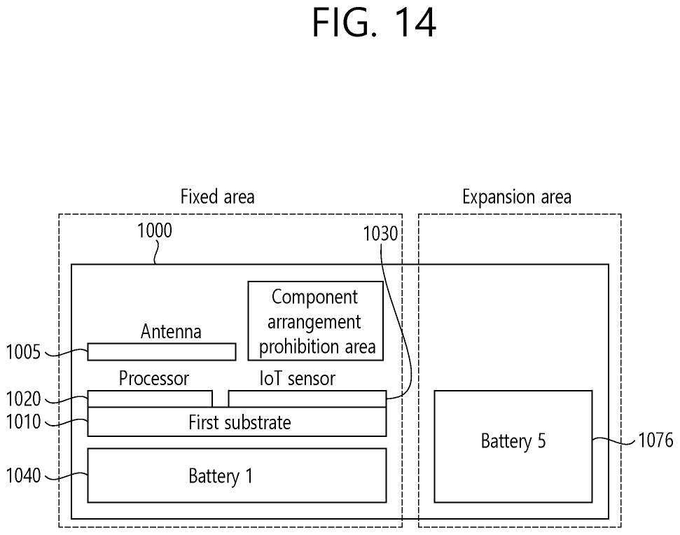

In addition, referring to FIG. 14, battery 5 1076 is internally modularized in the expansion area and configured in an expanded form within one IoT device.

By arranging derived components in an expansion area other than the component arrangement prohibition area, there is no need to consider the issues related to miniaturization, waterproofing, and dust proofing, the need for considering issues related to the performance of a communication module (processor) and an antenna is also obviated.

In particular, in addition to the component arrangement prohibition area, it is also desirable to prevent the RF performance of the communication module and the antenna from being affected by limiting the height of the expansion area to a reference value.

In this document, the present disclosure has been described with reference to appended drawings and embodiments, but the technical scope of the present disclosure is not limited to the drawings or embodiments. Rather, it should be understood by those skilled in the art to which the present disclosure belongs that the present disclosure may be modified or changed in various ways without departing from the technical principles and scope of the present disclosure described by the appended claims below.

What is claimed is:

1. An expandable modular IoT device comprising:
a first substrate;
a first processor on the first substrate;
a first IoT sensor on the first substrate; and
a connector configured to connect an additional electronic component.

2. The expandable modular IoT device of claim 1, further including a first battery arranged within the IoT device.

3. The expandable modular IoT device of claim 2, wherein the additional electronic component further includes a second battery and a power management circuit controlling power from the second battery,
wherein the power management circuit:
(i) supplies power from the first battery to the processor when only the first battery is connected and
(ii) supplies power from the second battery to the processor when the second battery arranged independently of the IoT device is connected to the connector.

4. The expandable modular IoT device of claim 3, wherein, when the connector is connected to a charging Universal Serial Bus (USB), the power management circuit supplies power to the processor at a second voltage through the charging USB,
wherein the second voltage is higher than a first voltage of the first battery or the second battery.

5. The expandable modular IoT device of claim 4, wherein, in response to the existence of the first battery with the connector connected to the charging USB, the power management circuit activates a mode for charging the first battery while supplying power to the processor at the second voltage.

6. The expandable modular IoT device of claim 1, wherein the additional electronic component includes a second substrate and a second IoT sensor on the second substrate, and
wherein, when the second substrate and the second IoT sensor are arranged inside the IoT device,
the connector is a first internal connector arranged on the first substrate,
a second internal connector is also arranged on the second substrate, and
wherein the first substrate and the second substrate are modularized and communicate within the IoT device due to a connection between the first internal connector and the second internal connector.

7. The expandable modular IoT device of claim 1, wherein the connector is a first external connector for connection with a second IoT device arranged independently of the IoT device,
wherein the second IoT device also includes a second processor, a second IoT sensor, and a second external connector and
wherein the first external connector is connected to the second external connector to enable the first processor to communicate with the second processor.

8. The expandable modular IoT device of claim 6 or 7, wherein communication manners through the connector includes at least one of the Universal Asynchronous Receive/Transmit (UART), Inter-Integrated Circuit (I2C), and Serial Peripheral Interface (SPI) communication.

9. The expandable modular IoT device of claim 1, wherein a communication manner between the first processor and the first IoT sensor uses a first communication manner,
wherein a communication manner between the first substrate and the second substrate within the IoT device through an internal connector uses a second communication manner, and
wherein a communication manner for a second IoT device through an external connector uses a third communication manner for transmission and reception of data.

10. An expandable modular IoT device comprising:
a first substrate;
a processor on the first substrate;
a first IoT sensor on the first substrate; and
an antenna operating in conjunction with the processor,
wherein other derived electronic components than the first substrate, the processor and the first IoT sensor are configured to be mounted inside the IoT device.

11. The expandable modular IoT device of claim 10, wherein a component arrangement prohibition area having a size greater than or equal to a reference value is set in a predetermined area of a side of the antenna in the horizontal direction from a bottom surface of the IoT device, and when the derived electronic component is expanded and made to operate in conjunction with other components, no component is configured to be arranged in the component arrangement prohibition area to prevent the Radio Frequency (RF) performance of the processor and the antenna from being affected.

12. The expandable modular IoT device of claim 11, wherein the antenna is arranged on top of the processor in the vertical direction from the bottom surface,
wherein the antenna is arranged around the first substrate in the horizontal direction, and
wherein the length of the antenna is shorter than the length of the first substrate by more than a reference length such that the component arrangement prohibition region is configured to secure the predetermined area in a marginal portion between the length of the first substrate and the length of the antenna.

13. The expandable modular IoT device of claim 12, wherein a fixed area is configured, which includes the antenna, the processor, the first IoT sensor, and the first substrate,
wherein the derived component is formed in an expansion area and operates in conjunction with a single IoT device,
wherein the expansion area is formed on a side of the fixed area in the horizontal direction.

14. The expandable modular IoT device of claim 13, wherein the expansion area has a limited space so that the expansion area's height does not exceed a reference value.

15. The expandable modular IoT device of claim 13, wherein the derived component includes at least one of a second substrate, a second IoT sensor, and a battery.
